(19) United States
(12) Patent Application Publication
(10) Pub. No.: US 2015/0076453 A1
(43) Pub. Date: Mar. 19, 2015

(54) ULTRAVIOLET ORGANIC LIGHT-EMITTING APPARATUS

(71) Applicants: Yawei Liu, Shenzhen (CN); Yi-fan Wang, Shenzhen (CN)

(72) Inventors: Yawei Liu, Shenzhen (CN); Yi-fan Wang, Shenzhen (CN)

(73) Assignee: Shenzhen China Star Optoelectronics Technology Co., Ltd, Shenzhen (CN)

(21) Appl. No.: 13/581,473

(22) PCT Filed: Jun. 21, 2012
(86) PCT No.: PCT/CN2012/077333

§ 371 Date: Aug. 28, 2012

(30) Foreign Application Priority Data
Jun. 4, 2012 (CN) 201210180247.7

(51) Int. Cl. H01L 51/52

(52) U.S. Cl. CPC H01L 51/5237
USPC 257/40

(57) ABSTRACT

The present invention provides an ultraviolet (UV) organic light-emitting apparatus. The UV organic light-emitting apparatus comprises a UV organic light-emitting device and a passivation layer. The UV organic light-emitting device comprises a first electrode, a UV organic material layer and a second electrode formed in sequence. The passivation layer is disposed at a light emitting side of the UV organic light-emitting device, wherein the passivation layer is made of a transparent material showing a weak absorption in a UV spectral region. The present invention can mitigate the problems existing in the conventional UV lamp.

### FIELD OF THE INVENTION

The present invention relates to an ultraviolet (UV) light field, and more particularly to a UV organic light-emitting apparatus for emitting UV light.

### BACKGROUND OF THE INVENTION

Ultraviolet (UV) light is electromagnetic radiation with a wavelength shorter than that of visible light, but longer than X-rays. It is named because the spectrum consists of electromagnetic waves with frequencies higher than those that humans identify as the colour violet.

UV light is found in sunlight and can be emitted by electric arcs and specialized lights such as black lights. It can cause chemical reactions, and causes many substances to glow or fluoresce. Although ultraviolet radiation is invisible to the human eye, most people are aware of the effects of UV through sunburn. However, the UV spectrum has many effects, both beneficial and damaging, to human health. For example, UV light is applicable to medical treatments.

However, a conventional UV light lamp, such as a mercury lamp, may have poisonous materials or gas and is breakable. Moreover, an irradiation area of the conventional UV light lamp is limited, and the conventional UV light lamp is difficult for portability.

As a result, it is necessary to provide a UV organic light-emitting apparatus to solve the problems existing in conventional technologies such as above-mentioned.

### SUMMARY OF THE INVENTION

The present invention provides a UV organic light-emitting apparatus to solve the problems existing in the conventional UV lamp.

A primary object of the present invention is to provide a UV organic light-emitting apparatus, and the UV organic light-emitting apparatus comprises: a UV organic light-emitting device comprising: a UV organic material layer for emitting a UV light; a first electrode formed at one side of the UV organic material layer; and a second electrode formed at another opposite side of the UV organic material layer; and a passivation layer disposed at a light emitting side of the UV organic light-emitting device, wherein the passivation layer is made of a transparent material showing a weak absorption in a UV spectral region.

A secondary object of the present invention is to provide a UV organic light-emitting apparatus, and the UV organic light-emitting apparatus comprises: a UV organic light-emitting device comprising: a UV organic material layer for emitting a UV light, wherein a band gap of a material of the UV organic material layer is greater than 3.1 eV; a first electrode formed at one side of the UV organic material layer; and a second electrode formed at another opposite side of the UV organic material layer; and a passivation layer disposed at a light emitting side of the UV organic light-emitting device, wherein the passivation layer is made of a transparent material showing a weak absorption in a UV spectral region, and an absorptivity of the transparent material to the UV light is less than an absorptivity of a glass substrate to the UV light.

In one embodiment of the present invention, the passivation layer is substrate structure, and the first electrode, the UV organic material layer and the second electrode are formed on the passivation layer in sequence.

In one embodiment of the present invention, the UV organic material layer is made of a UV organic material containing carbazole, fluorine, triphenylamine or quinquephenyl.

In one embodiment of the present invention, a band gap of a material of the UV organic material layer is greater than 3.1 eV.

In one embodiment of the present invention, the band gap of the material of the UV organic material layer is in a range of 3.1 eV to 3.9 eV.

In one embodiment of the present invention, the passivation layer is made of a quartz glass.

In one embodiment of the present invention, the passivation layer is made of Poly(methyl methacrylate).

In one embodiment of the present invention, the UV organic light-emitting device further comprises a substrate, and the first electrode, the UV organic material layer and the second electrode are stacked on the substrate in sequence.

In one embodiment of the present invention, a starting voltage of the UV organic light-emitting apparatus is lower than 10 V.

In one embodiment of the present invention, an absorptivity of the transparent material to the UV light is less than an absorptivity of a glass substrate to the UV light.

In comparison to the conventional UV lamp, the UV organic light-emitting apparatus of the present invention can have less poisonous materials or gas for reducing contamination. Moreover, the UV organic light-emitting apparatus of the present invention can mitigate the breakable problem and the limited irradiation area problem of the conventional UV lamp. In addition, the substrate of the UV organic light-emitting apparatus can be a flexible substrate, and thus it is allowable to be a portable apparatus, thereby improving the practicality and convenience thereof. Furthermore, the UV organic light-emitting apparatus can have a lower starting voltage, thereby having a higher power conversion efficiency.

The structure and the technical means adopted by the present invention to achieve the above-mentioned and other objects can be best understood by referring to the following detailed description of the preferred embodiments and the accompanying drawings:

### DESCRIPTION OF THE DRAWINGS

FIG. 1 is a schematic diagram showing a UV organic light-emitting apparatus according to one embodiment of the present invention;

FIG. 2 is a specific diagram showing the UV organic light-emitting apparatus according to one embodiment of the present invention;

FIG. 3 is a schematic diagram showing a UV organic light-emitting apparatus according to another embodiment of the present invention; and

FIG. 4 is a specific diagram showing the UV organic light-emitting apparatus according to another embodiment of the present invention.

### DETAILED DESCRIPTION OF THE PREFERRED EMBODIMENTS

The following embodiments are exemplified by referring to the accompanying drawings, for describing specific embodiments implemented by the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

In the drawings, like reference numerals indicate like components or items.

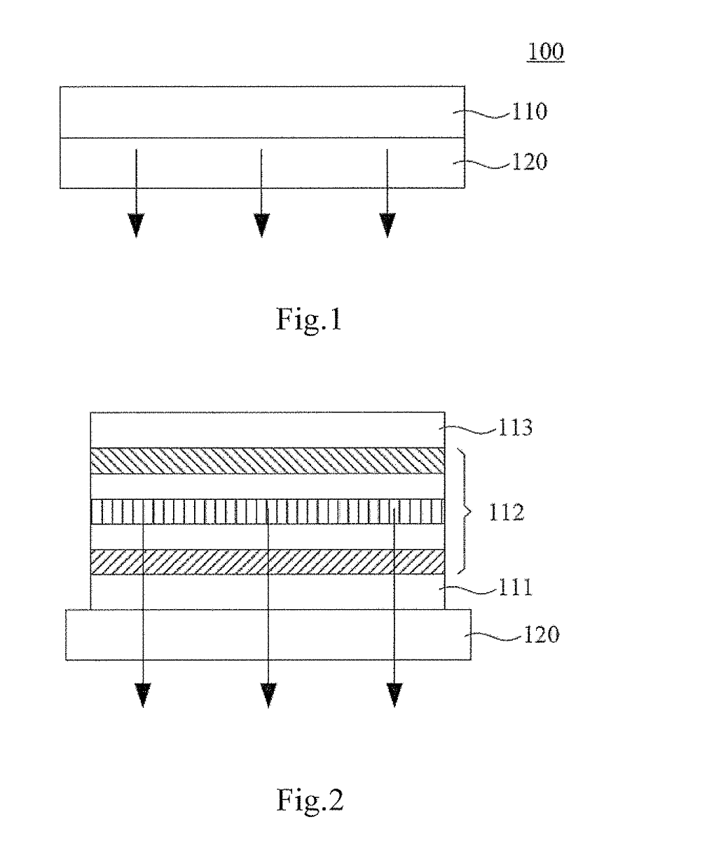

Referring to FIG. 1, a schematic diagram showing a UV organic light-emitting apparatus according to one embodiment of the present invention is illustrated. The UV organic light-emitting apparatus 100 can cat as a UV light source or a UV lamp. The UV organic light-emitting apparatus 100 can comprises a UV organic light-emitting device 110 and a passivation layer 120. The UV organic light-emitting device 110 is configured to emit a UV light having a wavelength which is less than 400 nm, such as in a range of 280 nm to 400 nm. The passivation layer 120 is disposed at a light emitting side of the UV organic light-emitting device 110 for protecting the UV organic light-emitting device 110, wherein the passivation layer 120 is made of a transparent material showing a weak absorption in a UV spectral region.

Referring to FIG. 2, a specific diagram showing the UV organic light-emitting apparatus according to one embodiment of the present invention is illustrated. The UV organic light-emitting device 110 can comprise a first electrode 111, a UV organic material layer 112 and a second electrode 113. The first electrode 111 is formed at one side of the UV organic material layer 112 to act as an anode, and the second electrode 113 is formed at another opposite side of the UV organic material layer 112 to act as a cathode. In the present embodiment, the UV organic light-emitting device 110 can be a bottom-emitting type organic light-emitting device, and the passivation layer 120 can be a substrate structure. At this time, the first electrode 111, the UV organic material layer 112 and the second electrode 113 are formed on the passivation layer 120 in sequence. The first electrode 111 is disposed close to the light emitting side of the UV organic light-emitting device 110. The first electrode 111 is preferably made of a transparent conductive material, such as ITO, IZO, AZO, GZO, TCO or ZnO, for allowing the UV light to pass through. The second electrode 113 may be made of Ag, Li, Mg, Al or any alloy thereof. The UV organic material layer 112 is configured to emit the UV light, and the material of the UV organic material layer 112 can have a wide band gap, and may be a UV organic material containing carbazole, fluorine, triphenylamine, quinquephenyl and the like, wherein a band gap of the UV organic material of the UV organic material layer 112 is preferably greater than 3.1 eV, such as in a range of 3.1 eV to 3.9 eV. In that manner, a wavelength of the UV light emitted by the UV organic material layer 112 can be less than 400 nm.

For example, in the UV organic material layer 112, the UV organic material containing carbazole has a band gap of about 3.25 eV and a spectral peak at about 394 nm. Moreover, for example, in the UV organic material layer 112, the UV organic material containing quinquephenyl has a band gap of about 3.48 eV and a spectral peak at about 310 nm.

In one embodiment, the UV organic material layer 112 may comprise a hole injection layer, a hole transportation layer, an emission layer, an electron transportation layer and an electron injection layer stacked on the first electrode 111 in sequence for improving a light emitting efficiency of the UV organic material layer 112.

In this embodiment, referring to FIG. 2 again, the passivation layer 120 is disposed at an outer side of the first electrode 111. The passivation layer 120 can be made of a transparent material showing a weak absorption in a UV spectral region, such as a quartz glass or an organic material (for example Poly(methyl methacrylate), PMMA), and an absorptivity of the transparent material to the UV light is less than an absorptivity of a glass substrate to the UV light, so as to prevent most of the UV light emitted by the UV organic material layer 112 from being absorbed by the passivation layer 120. Therefore, the passivation layer 120 can protect the UV organic light-emitting device 110 from environmental damages, and can ensure the light emitting efficiency thereof.

Therefore, the UV organic light-emitting apparatus 100 can be configured to emit the UV light. In comparison with the conventional UV lamp, with the use of the UV organic light-emitting apparatus 100, the use of poisonous materials or gas can be omitted or reduced to reduce contamination. Furthermore, the UV organic light-emitting apparatus 100 can act as a planar light source to mitigate the breakable problem, and can have a large irradiation area. In addition, the substrate (for example the passivation layer 120) of the UV organic light-emitting apparatus 100 can be a flexible substrate, and thus it is allowable to be a portable apparatus.

In this embodiment, a starting voltage of the UV organic light-emitting apparatus 100 can be lower than 10 V. Accordingly, in comparison with the conventional UV lamp, the UV organic light-emitting apparatus 100 of the present embodiment can have a lower energy consumption and a higher power conversion efficiency.

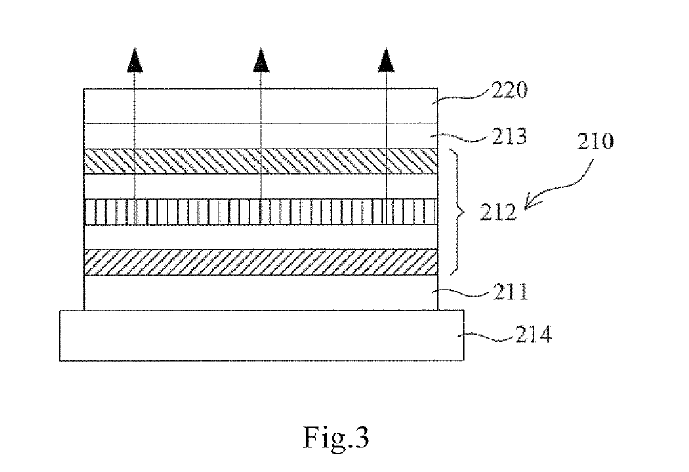

Referring to FIG. 3, a schematic diagram showing a UV organic light-emitting apparatus according to another embodiment of the present invention is illustrated. In another embodiment, the UV organic light-emitting device 210 can comprise a first electrode 211, a UV organic material layer 212, a second electrode 213 and a substrate 214. In this embodiment, the UV organic light-emitting device 210 can be a top-emitting type organic light-emitting device, and the passivation layer 220 can cover the second electrode 213 of the UV organic light-emitting device 210. At this time, the first electrode 211, the UV organic material layer 212 and the second electrode 213 are stacked on the substrate 214 in sequence. The material of the first electrode 211 may be a high reflective metal, such as silver, silver oxide, gold, aluminum or any alloy thereof. The second electrode 213 is disposed close to the light emitting side of the UV organic light-emitting device 210, and is preferably made of a transparent conductive material, such as ITO, IZO, AZO, GZO, TCO or ZnO, for allowing the UV light to pass through. The UV organic material layer 212 is configured to emit the UV light, and is preferably made of a material having a wide band gap. The substrate 214 may be a glass substrate, a flexible plastic substrate, a wafer substrate or a heat dissipation substrate for supporting the first electrode 211, the UV organic material layer 212 and the second electrode 213. The passivation layer 220 covers the second electrode 213 and protects the second electrode 213 from environmental damages. The passivation layer 220 can be made of a transparent material showing a weak absorption in the UV spectral region, such as quartz glass or organic material (for example PMMA), so as to prevent most of the UV light emitted by the UV organic material layer 212 from being absorbed by the passivation layer 220. In this embodiment, an absorptivity of the passivation layer 220 to the UV light is less than the absorptivity of the glass substrate to the UV light.

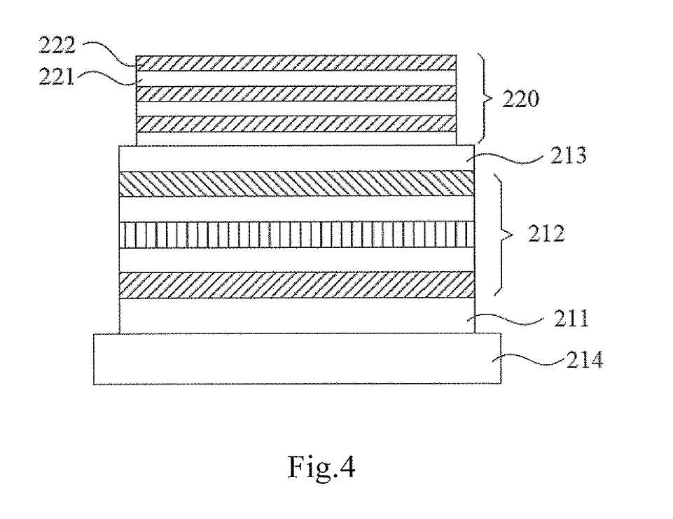

Referring to FIG. 4, a specific diagram showing the UV organic light-emitting apparatus according to another embodiment of the present invention is illustrated. In one embodiment, the passivation layer 220 may be made of a composite material. At this time, the passivation layer 220 can comprise sub-passivation layers 221 and organic layers 222 which are stacked on the second electrode 213 in an alternating manner. The material of the sub-passivation layers 221 may be SiNₓ and/or SiOₓ, and the organic layers 222 are configured to prevent the sub-passivation layers 221 from fragility, so as to enhance the structure of the passivation layer 220.

As described above, the UV organic light-emitting apparatus of the present invention can be used for emitting the UV light. In comparison with the conventional UV lamp, the UV organic light-emitting apparatus of the present invention can have less poisonous materials or gas for reducing contamination. Moreover, the UV organic light-emitting apparatus of the present invention can mitigate the breakable problem and the limited irradiation area problem. In addition, the substrate of the UV organic light-emitting apparatus can be a flexible substrate, and thus it is allowable to be a portable apparatus, thereby improving the practicality and convenience thereof. Furthermore, the UV organic light-emitting apparatus can have a lower starting voltage, thereby having a higher power conversion efficiency.

The present invention has been described with a preferred embodiment thereof and it is understood that many changes and modifications to the described embodiment can be carried out without departing from the scope and the spirit of the invention that is intended to be limited only by the appended claims.

1. An ultraviolet (UV) organic light-emitting apparatus, comprising:
a UV organic light-emitting device comprising:
a UV organic material layer for emitting a UV light, wherein a band gap of a material of the UV organic material layer is greater than 3.1 eV;
a first electrode formed at one side of the UV organic material layer; and
a second electrode formed at another opposite side of the UV organic material layer; and
a passivation layer disposed at a light emitting side of the UV organic light-emitting device, wherein the passivation layer is made of a transparent material showing a weak absorption in a UV spectral region, and an absorptivity of the transparent material to the UV light is less than an absorptivity of a glass substrate to the UV light.

2. The UV organic light-emitting apparatus according to claim 1, wherein the passivation layer is substrate structure, and the first electrode, the UV organic material layer and the second electrode are formed on the passivation layer in sequence.

3. The UV organic light-emitting apparatus according to claim 1, wherein the UV organic material layer is made of a UV organic material containing carbazole, fluorine, triphenylamine or quinquephenyl.

4. The UV organic light-emitting apparatus according to claim 1, wherein the band gap of the material of the UV organic material layer is in a range of 3.1 eV to 3.9 eV.

5. The UV organic light-emitting apparatus according to claim 1, wherein the passivation layer is made of a quartz glass.

6. The UV organic light-emitting apparatus according to claim 1, wherein the passivation layer is made of Poly(methyl methacrylate).

7. The UV organic light-emitting apparatus according to claim 1, wherein the UV organic light-emitting device further comprises a substrate, and the first electrode, the UV organic material layer and the second electrode are stacked on the substrate in sequence.

8. The UV organic light-emitting apparatus according to claim 1, wherein a starting voltage of the UV organic light-emitting apparatus is lower than 10 V.

9. A UV organic light-emitting apparatus, comprising:
a UV organic light-emitting device comprising:
a UV organic material layer for emitting a UV light;
a first electrode formed at one side of the UV organic material layer; and
a second electrode formed at another opposite side of the UV organic material layer; and
a passivation layer disposed at a light emitting side of the UV organic light-emitting device, wherein the passivation layer is made of a transparent material showing a weak absorption in a UV spectral region.

10. The UV organic light-emitting apparatus according to claim 9, wherein the passivation layer is substrate structure, and the first electrode, the UV organic material layer and the second electrode are formed on the passivation layer in sequence.

11. The UV organic light-emitting apparatus according to claim 9, wherein the UV organic material layer is made of a UV organic material containing carbazole, fluorine, triphenylamine or quinquephenyl.

12. The UV organic light-emitting apparatus according to claim 9, wherein a band gap of a material of the UV organic material layer is greater than 3.1 eV.

13. The UV organic light-emitting apparatus according to claim 12, wherein the band gap of the material of the UV organic material layer is in a range of 3.1 eV to 3.9 eV.

14. The UV organic light-emitting apparatus according to claim 9, wherein the passivation layer is made of a quartz glass.

15. The UV organic light-emitting apparatus according to claim 9, wherein the passivation layer is made of Poly(methyl methacrylate).

16. The UV organic light-emitting apparatus according to claim 9, wherein the UV organic light-emitting device further comprises a substrate, and the first electrode, the UV organic material layer and the second electrode are stacked on the substrate in sequence.

17. The UV organic light-emitting apparatus according to claim 9, wherein a starting voltage of the UV organic light-emitting apparatus is lower than 10 V.

18. The UV organic light-emitting apparatus according to claim 9, wherein an absorptivity of the transparent material to the UV light is less than an absorptivity of a glass substrate to the UV light.
